(19) United States
(12) Patent Application Publication
(10) Pub. No.: US 2013/0234232 A1
(43) Pub. Date: Sep. 12, 2013

(54) METHOD FOR MANUFACTURING SEMICONDUCTOR DEVICE AND SEMICONDUCTOR DEVICE

(71) Applicant: Katsunori YAHASHI, Mie-ken (JP)

(72) Inventor: Katsunori YAHASHI, Mie-ken (JP)

(73) Assignee: Kabushiki Kaisha Toshiba, Tokyo (JP)

(21) Appl. No.: 13/603,616

(22) Filed: Sep. 5, 2012

(30) Foreign Application Priority Data
Mar. 5, 2012 (JP) 2012-048449

(51) Int. Cl. H01L 21/768; H01L 29/792

(52) U.S. Cl. CPC H01L 21/768; H01L 29/792
USPC 257/324; 438/637

(57) ABSTRACT

According to one embodiment, a method of manufacturing a semiconductor device includes forming a part of a stacked body including a plurality of conductive films and a plurality of first insulating films alternately stacked into a shape of steps to form a plurality of stepped portions of different heights, each stepped portion having the first insulating film as a top face. The method includes forming gaps under ends of the first insulating films by removing ends of the conductive films under the first insulating films in the stepped portions. The method includes forming second insulating films on the respective stepped portions and in the gaps. The method includes forming a plurality of vias, each of the vias penetrating through the second insulating film and the first insulating film in each stepped portion and reaches the conductive film in each stepped portion.

### CROSS-REFERENCE TO RELATED APPLICATION

This application is based upon and claims the benefit of priority from Japanese Patent Application No. 2012-048449, filed on Mar. 5, 2012; the entire contents of which are incorporated herein by reference.

### FIELD

Embodiments described herein relate generally to a method for manufacturing a semiconductor device and a semiconductor device.

### BACKGROUND

A three-dimensionally structured memory device is proposed in which a memory hole is formed in a stacked body where a plurality of conductive films functioning as a control gate in a memory cell and insulating films are alternately stacked, and in which a silicon body serving as a channel through a charge storage film is provided on a side wall of the memory hole.

As a configuration for connecting each of the plurality of stacked conductive films to other interconnection, a configuration of the plurality of conductive films formed to be step-like is proposed. In the step-like contact configuration, displacement of a via relative to stepped portions can lead to short-circuit between the upper and lower conductive films.

### BRIEF DESCRIPTION OF THE DRAWINGS

FIG. 1 is a schematic plan view showing positional relationship between a memory cell array and a stepped contact portion in a semiconductor device of an embodiment;

FIG. 2 is a schematic perspective view of the memory cell array in the semiconductor device of the embodiment;

FIG. 3 is an enlarged sectional view of a columnar portion of a memory string shown in FIG. 2;

FIGS. 4A to 8B are schematic sectional views showing a method for forming a stepped contact portion of a first embodiment;

FIGS. 9A to 9C are schematic sectional views showing a method for forming a stepped contact portion of a second embodiment;

FIGS. 10A to 11C are schematic sectional views showing a method for forming a stepped contact portion of a third embodiment;

FIGS. 12A to 12B are schematic sectional views of a stepped contact portion in a comparative example; and

FIG. 13A is a schematic sectional view of the stepped contact portion in the comparative example, FIG. 13B is a schematic sectional view of the stepped contact portion in the embodiment.

### DETAILED DESCRIPTION

According to one embodiment, a method of manufacturing a semiconductor device includes forming a part of a stacked body including a plurality of conductive films and a plurality of first insulating films alternately stacked into a shape of steps to form a plurality of stepped portions of different heights, each stepped portion having the first insulating film as a top face. The method includes forming gaps under ends of the first insulating films by removing ends of the conductive films under the first insulating films in the stepped portions. The method includes forming second insulating films having a material different from a material for the first insulating films on the respective stepped portions and in the gaps. The method includes forming a plurality of vias, each of the vias penetrating through the second insulating film and the first insulating film in each stepped portion and reaches the conductive film in each stepped portion.

Embodiments of the invention will now be described with reference to the drawings. In the drawings, the same components are marked with like reference numerals.

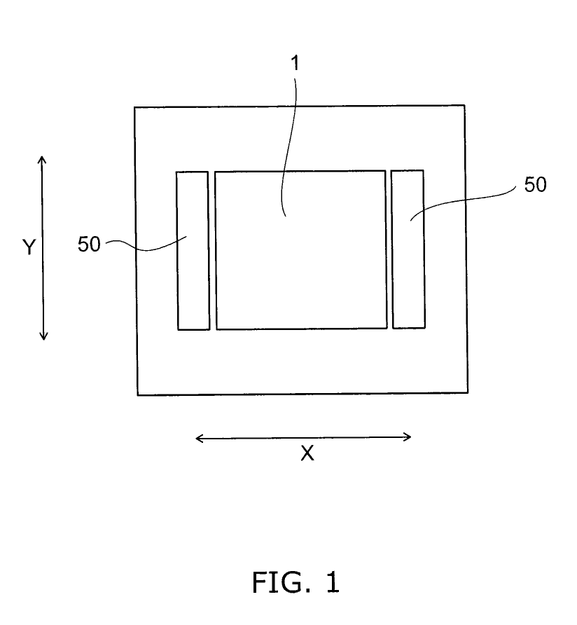

FIG. 1 is a schematic plan view showing positional relationship between a memory cell array 1 and a stepped contact portion 50 in a semiconductor device of the embodiment. FIG. 1 corresponds to an area of one chip.

The memory cell array 1 is formed at the center of the chip. The stepped contact portion 50 is formed on the outer side of the memory cell array 1 in a first direction (X direction). A circuit for driving the memory cell array 1 and the like are formed in an area surrounding the memory cell array 1 and the stepped contact portion 50.

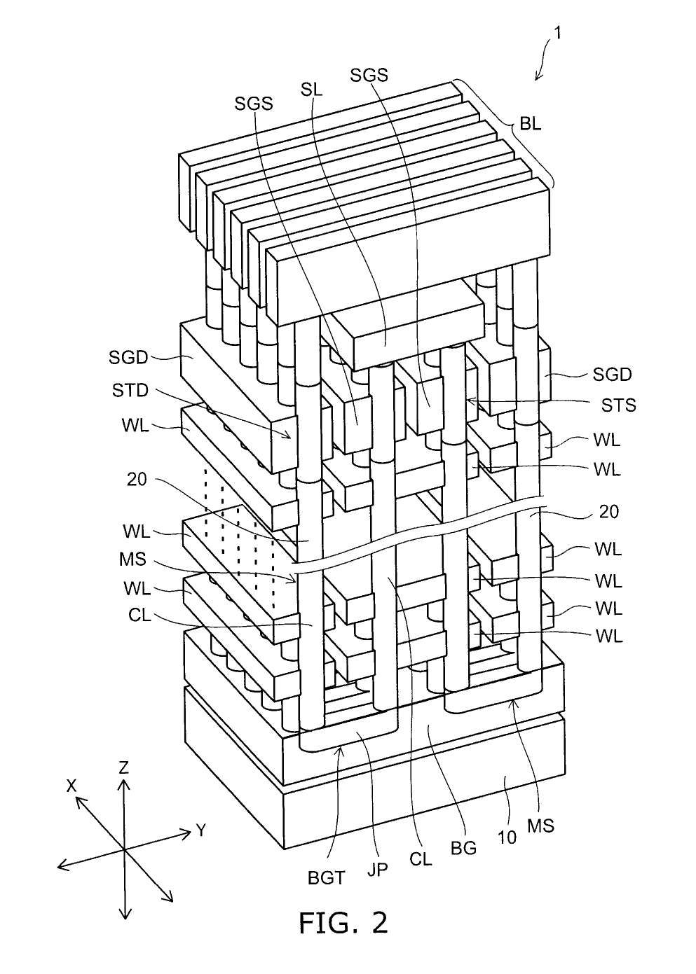

FIG. 2 is a schematic perspective view of the memory cell array 1. For clarification, an insulating part is not shown in FIG. 2.

An XYZ Cartesian coordinate system is introduced in FIG. 2. Two directions that are parallel to a major surface of a substrate 10 and are orthogonal to each other are defined as an X direction (first direction) and a Y direction (second direction), and a direction that is orthogonal to both the X direction and the Y direction is defined as a Z direction (third direction or stacking direction).

The memory cell array 1 has a plurality of memory strings MS. One of the memory strings MS is a U-shaped body having a pair of columnar portions CL, and a joining portion JP that joins lower ends of the pair of columnar portions CL together.

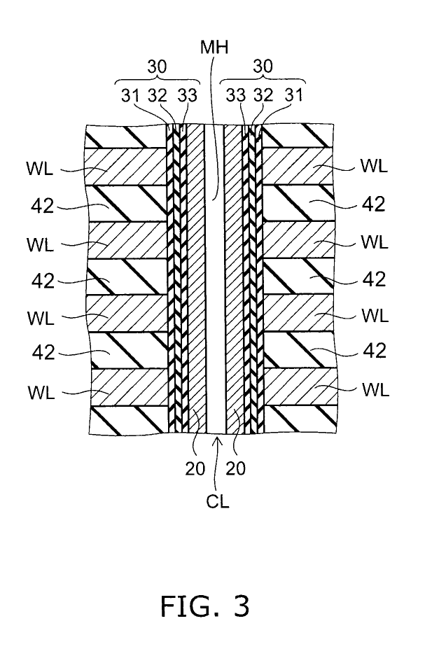

FIG. 3 is an enlarged sectional view of the columnar portions CL of the memory strings MS.

As shown in FIG. 2, a back gate BG is provided on the substrate 10. The back gate BG is a conductive film such as a silicon film to which an impurity is added.

A plurality of insulating films 42 (shown in FIG. 3) and a plurality of conductive films WL are alternately stacked on the back gate BG. The insulating film 42 is provided between the conductive films WL. The number of the conductive films WL and the insulating films 42 is optional.

The conductive film WL functions as an electrode, and for example, is a poly-silicon film to which an impurity is added. Other examples of the conductive film WL include a nickel silicide film, a cobalt silicide film, a titanium silicide film, a tungsten silicide film, a tungsten film, a titanium nitride film, a titanium film, and an aluminum film.

The insulating film 42 is, for example, a silicon oxide film. Other examples of the insulating film 42 include a silicon nitride film, aluminum oxide film, an aluminum nitride film, a titanium oxide film, and a tungsten oxide film.

A drain-side selection gate SGD is provided at one end of the pair of columnar portions CL of the U-shaped memory string MS, and a source-side selection gate SGS is provided at the other end. The drain-side selection gate SGD and the source-side selection gate SGS are provided on the uppermost conductive film WL. The drain-side selection gate SGD and the source-side selection gate SGS are conductive films such as poly-silicon films to which an impurity is added.

The drain-side selection gate SGD is separated from the source-side selection gate SGS in the Y direction. The conductive films WL stacked below the drain-side selection gate SGD are separated from the conductive films WL stacked below the source-side selection gate SGS in the Y direction.

A source line SL is provided above the source-side selection gate SGS. The source line SL is, for example, a metal film.

Bit lines BL as a plurality of metal wires are provided above the drain-side selection gate SGD and the source line SL. Each of the bit lines BL extends in the Y direction.

The memory string MS has channel body 20 (shown in FIG. 3) provided in an U-shaped memory hole MH formed in a stacked body including the back gate BG, the plurality of conductive films WL, the plurality of insulating films 42, the drain-side selection gate SGD and the source-side selection gate SGS.

The channel body 20 is provided in the U-shaped memory hole MH across a memory film 30. The channel body 20 is, for example, a silicon film. The memory film 30 is, as shown in FIG. 3, provided between an inner wall (side wall and bottom wall) of the memory hole MH and the channel body 20.

Although FIG. 3 shows a configuration in which the channel body 20 is provided such that a cavity is left on the side of the central axis of the memory hole MH, the entire memory hole MH may be filled with the channel body 20 or an insulator may be buried in the cavity on the inner side of the channel body 20.

The memory film 30 has a block film 31, a charge storage film 32, and a tunnel film 33. The block film 31, the charge storage film 32, and the tunnel film 33 are provided between the conductive films WL and the channel body 20 in this order from the side of the conductive films WL. The block film 31 is in contact with the conductive films WL, the tunnel film 33 is in contact with the channel body 20, and the charge storage film 32 is provided between the block film 31 and the tunnel film 33.

The channel body 20 functions as a channel in the memory cell, the conductive films WL function as control gates, and the charge storage film 32 functions as a data storage layer that accumulates charges injected from the channel body 20. That is, the memory cell in which the control gate surrounds the channel is formed at an intersection of the channel body 20 and each conductive film WL.

The semiconductor device in the embodiments is a nonvolatile semiconductor storage device that electrically erases and writes data without restraint, and holds stored contents even after power-off.

The memory cell is, for example, a charge trap-type memory cell. The charge storage film 32 has a lot of trap sites that captures charges and is, for example, a silicon nitride film.

The tunnel film 33 is, for example, a silicon oxide film, and becomes a charge barrier when charges are injected from the channel body 20 into the charge storage film 32, or when charges accumulated in the charge storage film 32 are diffused to the channel body 20.

The block film 31 is, for example, a silicon oxide film, and prevents the charges accumulated in the charge storage film 32 from being diffused to the conductive films WL.

The drain-side selection gate SGD, the channel body 20, and the memory film 30 therebetween constitute a drain-side selection transistor STD. Above the drain-side selection gate SGD, the channel body 20 is connected to the bit lines BL.

The source-side selection gate SGS, the channel body 20 and the memory film 30 therebetween constitute a source-side selection transistor STS. Above the source-side selection gate SGS, the channel body 20 is connected to the source line SL.

The back gate BG, and the channel body 20 and the memory film 30 that are provided in the back gate BG constitute a back gate transistor BGT.

The plurality of memory cells using each conductive film WL as the control gate are provided between the drain-side selection transistor STD and the back gate transistor BGT. Similarly, the plurality of memory cells using each conductive film WL as the control gate are also provided between the back gate transistor BGT and the source-side selection transistor STS.

The plurality of memory cells, the drain-side selection transistor STD, the back gate transistor BGT and the source-side selection transistor STS are serially connected to one another via the channel body 20 to constitute one U-shaped memory string MS. The plurality of memory strings MS are arranged in the X direction and the Y direction, resulting in that the plurality of memory cells MC are three-dimensionally provided in the X direction, the Y direction, and the Z direction.

Each of the plurality of conductive films including the back gate BG and the conductive films WL in the memory cell array 1 is connected to circuit interconnection via the stepped contact portion 50.

### First Embodiment

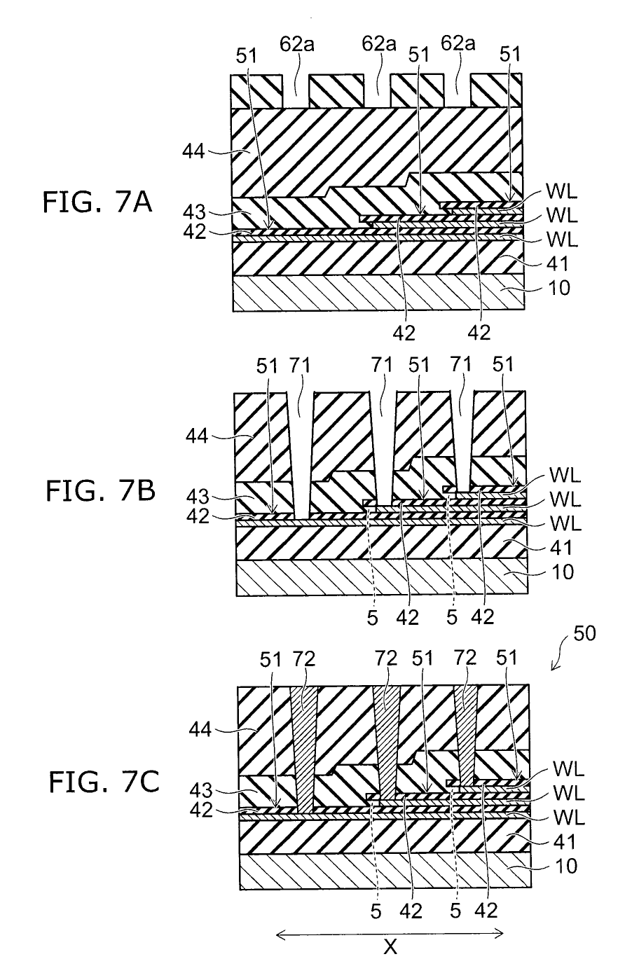

FIG. 7C is a schematic sectional view of the stepped contact portion 50 in First embodiment. A cross section in FIG. 7C corresponds to a cross section along the X direction in FIG. 1 and FIG. 2.

The stacked body including the plurality of conductive films WL on the substrate 10 is common to the memory cell array 1 and the stepped contact portion 50. Accordingly, although a conductive film corresponding to the back gate BG is provided above the substrate 10 via an insulating film 41 also in the stepped contact portion 50, it is omitted in FIG. 7C. The number of layers of the conductive films WL is not limited to the illustrated one and is optional.

The stacked body including the plurality of insulating films (hereinafter also referred to as first insulating films) 42 and the plurality of conductive films WL is also formed in an area on the outer side of a chip center area in the X direction, in which the memory cell array 1 is formed. The stepped contact portion 50 is provided in the stacked body in the area.

In the stepped contact portion 50, the plurality of conductive films WL and the insulating films 42 are stepped in the X direction. That is, the stepped contact portion 50 has a plurality of stepped portions 51.

The heights of the plurality of stepped portions 51 from the substrate 10 vary. Each stepped portions 51 includes one conductive film WL and one first insulating film 42 provided on the conductive film WL, and a top face of each stepped portions 51 is the first insulating film 42.

A second insulating film 43 having a material that is different from a material for the first insulating film 42 is provided on the stepped portion 51. The first insulating film 42 is, for example, a silicon oxide film, and the second insulating film 43 is, for example, a silicon nitride film.

The second insulating film 43 covers the top face and an end of each stepped portions 51. The second insulating film 43, not the conductive film WL, is provided under the end of the first insulating film 42 in each stepped portion 51. That is, in each stepped portions 51, the end of the first insulating films 42 protrudes outward from the end of the conductive film WL immediately under the first insulating films 42. The second insulating film 43 is provided under the protruding end of the first insulating films 42.

After the stepped portion 51 is formed, as described later, the end of the conductive film WL is removed, and a gap 5 is formed under the end of the first insulating film 42. The second insulating film 43 is buried in the gap 5.

The first insulating film 42 in a stage under is provided under the second insulating film 43 provided in the gap 5. That is, the second insulating film 43 provided in the gap 5 is held between the first insulating films 42.

A third insulating film 44 having a material that is different from the material for the second insulating film 43 is provided on the second insulating film 43. The third insulating film 44 is, for example, a silicon oxide film. The third insulating film 44 is thicker than the second insulating film 43. The third insulating film 44 is thicker than the first insulating film 42.

A plurality of vias 72 is provided on each stepped portion 51. Each via 72 penetrates through the third insulating film 44, the second insulating film 43, and the first insulating films 42 of each stepped portion 51, and reaches the conductive film WL of each stepped portion 51. Each via 72 is electrically connected to the conductive film WL of each corresponding stepped portion 51. One via 72 is connected to only the conductive film WL in one corresponding layer.

The via 72 includes, for example, barrier metal and buried metal. The barrier metal that adds adhesiveness and prevents diffusion of metal is formed on an inner wall of a hole 71 shown in FIG. 7B, and the buried metal having an excellent burying property is buried in the inner side of the barrier metal. For example, titanium nitride can be used as the barrier metal, and tungsten can be used as the buried metal.

Each of the conductive films WL in each layer of the stepped contact portion 50 is integrally connected to the conductive film WL in each layer of the memory cell array 1. Accordingly, each conductive film WL of the memory cell array 1 is connected to interconnection not shown provided on the stacked body via the via 72 of the stepped contact portion 50. The interconnection is connected to a circuit formed on the surface of the substrate 10 via the via not shown.

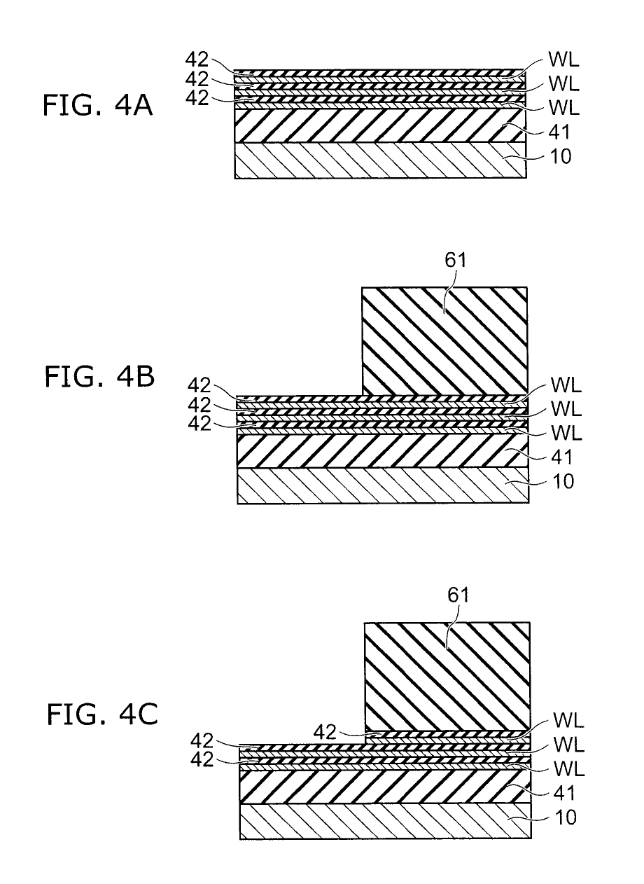

Next, with reference to FIG. 4A to FIG. 7C, a method of forming the stepped contact portion 50 in accordance with First embodiment will be described.

As shown in FIG. 4A, the conductive film WL and the first insulating film 42 are alternately stacked on the substrate 10 via the insulating film (for example, silicon oxide film) 41 to form the stacked body including the plurality of conductive films WL and the plurality of first insulating films 42. The insulating film 41, the conductive films WL, and the first insulating films 42 are formed according to a CVD (chemical vapor deposition) method, for example.

In the stacked body on the substrate 10, the memory cell array 1 shown in FIG. 2 is formed in the memory cell array area.

That is, the above-mentioned U-shaped memory hole MH is formed in the stacked body and then, the memory film 30 is formed on the inner wall (side wall and bottom wall) of the memory hole MH, and the channel body 20 is formed on the inner side of the memory film 30.

As described below, the stepped contact portion 50 is formed in an area on the outer side of the memory cell array 1 in the stacked body in the X direction.

First, a resist film 61 shown in FIG. 4B on the stacked body, and the resist film 61 is exposed, developed and patterned.

Then, using the resist film 61 as a mask, the stacked body is etched according to a RIE (Reactive Ion Etching) method, for example. First, as shown in FIG. 4C, the first insulating film 42 in the top layer and the conductive film WL in the top layer, which are exposed on the resist film 61, are removed.

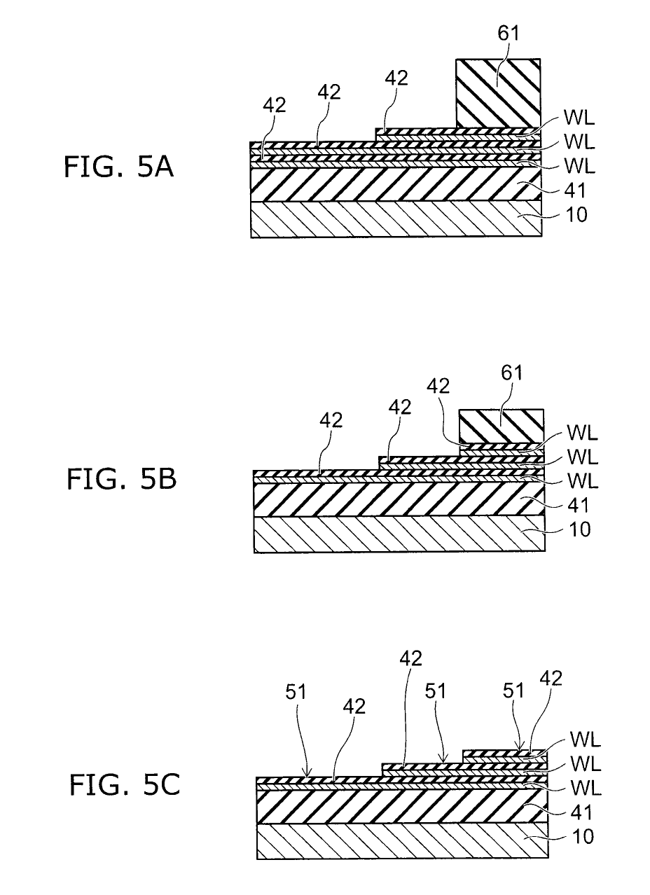

Next, the resist film 61 is subjected to ashing treatment using, for example, gas containing oxygen. Thereby, as shown in FIG. 5A, the resist film 61 is isotropically etched in the thickness direction and the plane direction, thereby increasing the area in the stacked body, which is exposed on the resist film 61.

Using the slimmed resist film 61 as a mask, the stacked body is further subjected to RIE. Also at this time, the first insulating films 42 in the top layer and the conductive films WL in the top layer, which are exposed on the resist film 61, are removed.

Also in the area previously etched by RIE, the first insulating film 42 in one layer and conductive film WL in one layer are further etched and removed.

After that, similarly, as shown in FIG. 5B, the resist film 61 is slimmed, and using the slimmed resist film 61 as a mask, the first insulating film 42 in one layer and the conductive film WL in one layer are etched.

Slimming of the resist film 61, and etching of the first insulating film 42 in one layer and the conductive film WL in one layer are repeated the number of times corresponding to the number of conductive films WL.

Then, the resist film 61, and as shown in FIG. 5C, the plurality of stepped portions 51 are formed in the stacked body.

The top face of each stepped portion 51 is the first insulating film 42. At this time, the first insulating film 42 and the conductive film WL under the first insulating film 42, which constitute each stepped portion 51, are the same as each other in plane size. That is, the end of the first insulating film 42 and the end of the conductive film WL in each stepped portion 51 are aligned in the plane direction (direction parallel to the major surface of the substrate 10).

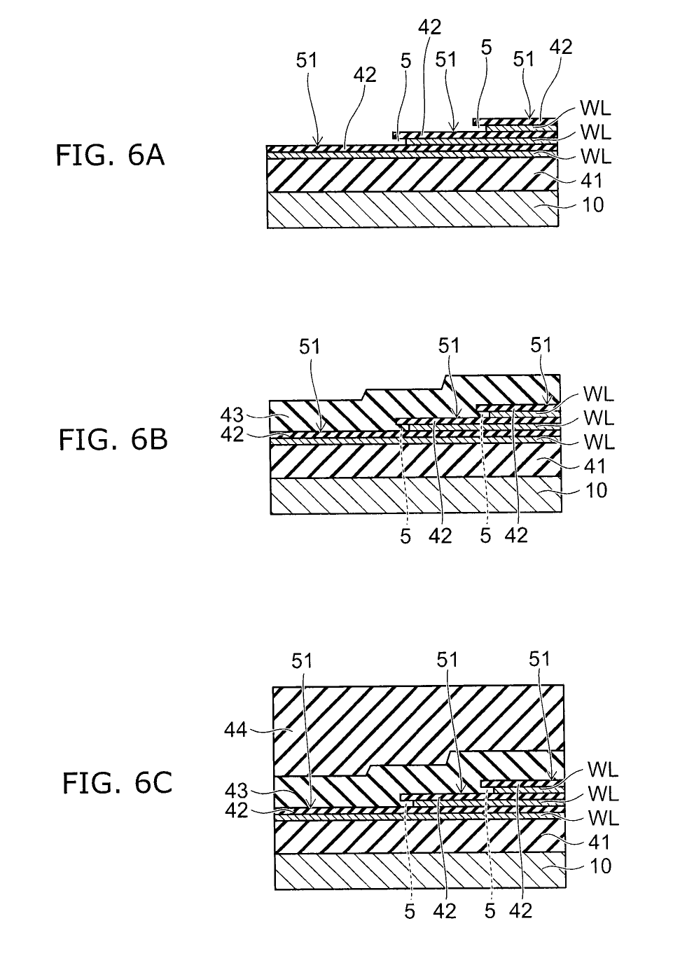

After the stepped portions 51 are formed, as shown in FIG. 6A, each gap 5 is formed under the end of the first insulating film 42.

For example, the conductive film WL as the silicon film is subjected to isotropic dry etching using gas containing fluorine, thereby removing the end of the conductive film WL to form the gap 5. At this time, etching of the first insulating film 42 that is different from the conductive film WL, such as the silicon oxide film, is suppressed. The end of the first insulating film 42 protrudes like a canopy above the gap 5.

At the above-mentioned etching of removing one first insulating film 42 and one conductive film WL in the stacking direction, a bias is applied to the substrate 10 to mainly use an impact force caused by ions accelerated toward the substrate 10.

On the contrary, at etching of forming the gap 5, a bias is not applied to the substrate 10, and a radical chemical action is mainly used.

After forming of the gap 5, as shown in FIG. 6B, the second insulating film 43 that is different from the first insulating films 42, such as the silicon nitride film, is formed on the stepped portions 51. The second insulating film 43 is formed according to the CVD method, for example. The second insulating film 43 is formed also in the gaps 5 and buried in the gaps 5.

Next, the third insulating film 44 that is different from the second insulating film 43, such as the silicon nitride film, is formed on the second insulating film 43 according to the CVD method, for example. A top face of the third insulating film 44 is flattened.

As shown in FIG. 7A, a resist film 62 is formed on the top face of the third insulating film 44. The resist film 62 is exposed and developed to form openings 62a. Then, using the resist film 62, portions exposed on the openings 62a are etched by (for example, RIE).

First, the third insulating film 44 is etched. The second insulating film 43 having the material that is different from the material for the third insulating film 44 functions as an etching stop film at this time. Subsequently, the second insulating film 43 is etched, and the uppermost first insulating film 42 in each stepped portion 51 is etched.

In this manner, as shown in FIG. 7B, the plurality of hole 71 that pass through the third insulating film 44, the second insulating film 43 and the first insulating films 42 and reach the conductive film WL of each stepped portion 51 are formed together at the same time.

Etching of the third insulating film 44, the second insulating film 43, and the first insulating films 42 is sequentially performed in the same chamber while changing etching conditions such as gas type without causing atmosphere break (vacuum break).

After that, as shown in FIG. 7C, the vias 72 are buried into the respective holes 71, resulting in that the conductive film WL in each layer is connected to the via 72.

### Comparative Example

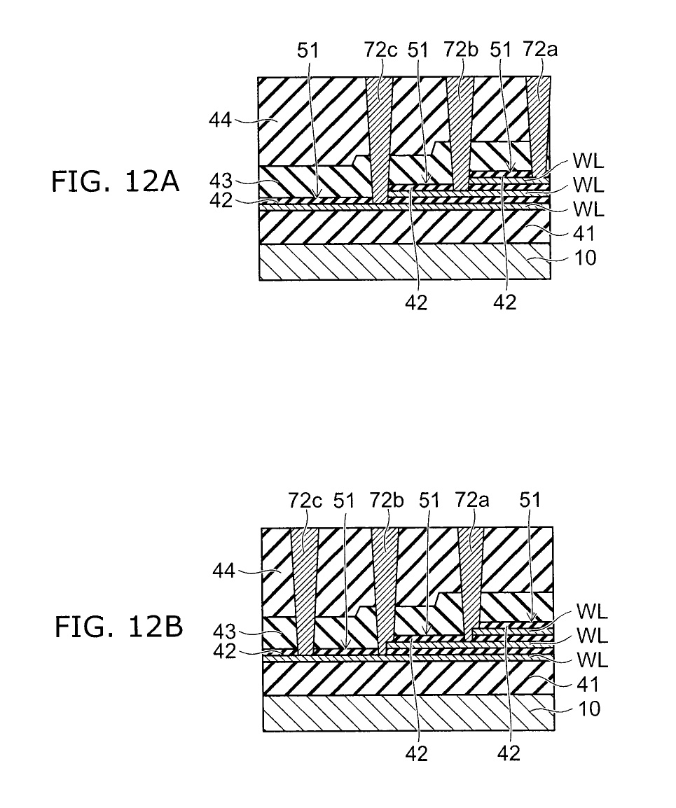

A stepped contact portion in a comparative example will be described with reference to FIG. 12A and FIG. 12B.

In the comparative example, since no gap is formed under the end of the first insulating film 42 in the stepped portion 51, the second insulating film 43 is not provided under the end of the first insulating films 42. That is, the end of the first insulating film 42 and the end of the conductive films WL in each stepped portion 51 are aligned in the plane direction. FIG. 12A shows a state where a central via 72b and a left via 72c are shifted to the right from desired positions and thus, side faces of the vias 72b, 72c contact the end of the conductive film WL to be unconnected, which is located in an upper stage than the stepped portion 51 to be connected.

That is, in this figure, the conductive films WL in the top layer and the conductive films WL in the second top layer become short-circuited to each other via the via 72b, and the conductive film WL in the second top layer and the conductive film WL in the third top layer become short-circuited to each other via the via 72c.

FIG. 12B shows a case where the central via 72b and a right via 72a are shifted to the left from desired positions and thus, a part of bottoms of the vias 72b, 72a is displaced from the stepped portion 51 to be connected and reaches the conductive film WL to be unconnected, which is located in a lower stage than the stepped portion 51 to be connected.

That is, in this figure, the conductive film WL in the top layer and the conductive film WL in the second top layer become short-circuited to each other via the via 72a, and the second top conductive films WL and the conductive film WL in the third top layer become short-circuited to each other via the via 72b.

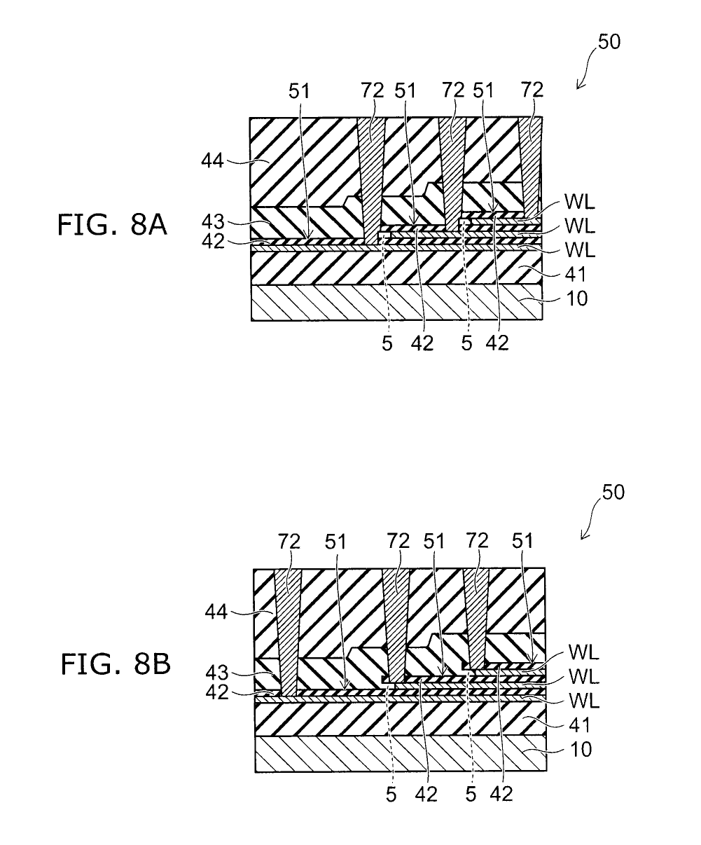

On the contrary, in the embodiments, as shown in FIG. 8A, even when the via 72 is shifted to the right from the desired position so as to contact the end of the first insulating film 42 in another stepped portion (the stepped portion in the upper stage than the stepped portion to be connected) 51, since the conductive film WL is not provided under the end of the first insulating film 42 and the second insulating film 43 is provided under the end of the first insulating film 42, it can be prevented that the via 72 contacts the conductive film WL to be unconnected in another layer (upper stage).

Further, in the embodiments, as shown in FIG. 8B, even when the via 72 is shifted to the left from the desired position and a part of the bottom of the via 72 is displaced outward from the conductive film WL to be connected, since the second insulating film 43 is provided on the outer side of the end of the conductive film WL, it can be prevented that a part of the via 72 reaches the conductive film WL to be unconnected in another layer (lower stage). That is, when the first insulating films 42 is etched, the second insulating film 43 under the end of the first insulating films 42 functions as an etching stopper, thereby suppressing etching of the lower layer.

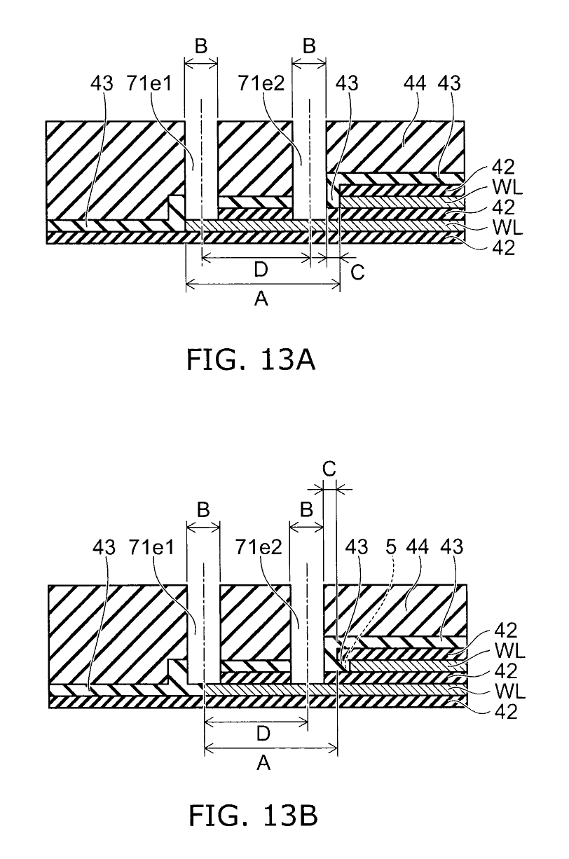

FIG. 13A is a schematic sectional view of the stepped contact portion in the comparative example. The position of a hole 71e1 and the position of a hole 71e2 are terminal positions where the holes can be located in the stepped portion to be connected such that the upper and lower conductive films WL are not short-circuited to each other.

D represents a range in which a central axis of the hole, which is represented by a chain line, can be located on the stepped portion to be connected. A represents a width of the stepped portion, and B represents a diameter of the hole. It is desired that a distance C between the hole 71e2 and the end of another stepped portion (in this figure, the stepped portion in the upper stage) is not less than 30 nm in order to ensure insulating resistance between the via and the conductive film WL in another stepped portion.

Therefore, in the comparative example, the range D in which the central axis of the hole can be located is A-C-B.

FIG. 13B is a schematic sectional view of the stepped contact portion in the embodiments. Also in this figure, the position of the hole 71e1 and the position of the hole 71e2 are terminal positions where the holes can be located in the stepped portion to be connected such that the upper and lower conductive films WL are not short-circuited to each other. Also in the embodiment, it is desired that a distance C between the hole 71e2 and the end of another stepped portion (in this figure, the stepped portion in the upper stage) is not less than 30 nm in order to ensure insulating resistance between the via and the conductive film WL in another stepped portion.

In the embodiment, as described above with reference to FIG. 8B, the hole 71e1 can be protruded outward from the conductive film WL to be connected. For example, given that a protruding amount of the hole 71e1 is a radius of the hole 71e1, in this embodiment, the range D in which the central axis of the hole can be located becomes A-C-(B/2), which is larger than that in the comparative example.

That is, in the embodiment, an allowable width of displacement of the hole in the stepped contact portion can be made larger than that in the comparative example. As a result, the possibility that the upper and lower conductive films WL become short-circuited to each other can be reduced, thereby improving reliability and cutting process costs.

### Second Embodiment

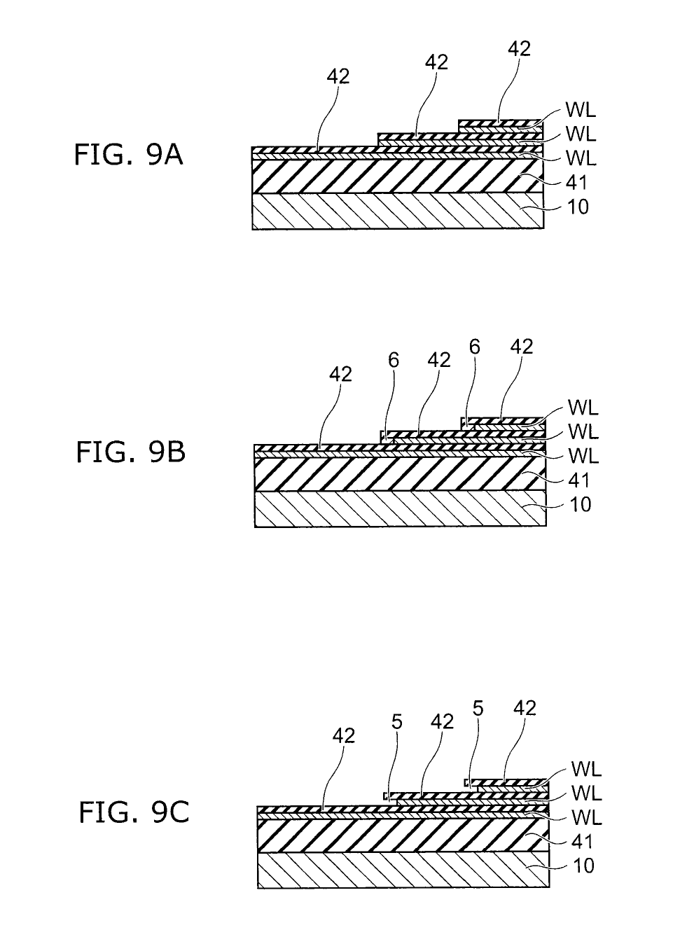

Next, with reference to FIG. 9A to FIG. 9C, a method of forming a stepped contact portion in Second embodiment will be described.

In Second embodiment, the conductive films WL are metal films, metal silicide films or the like, and include metal. As in First embodiment, the stacked body including the plurality of conductive films WL and the plurality of first insulating films 42 is formed to be step-like as shown in FIG. 9A.

Then, the end of the conductive film WL in each stepped portion gets oxidized to form a metal oxide 6 at the end of the conductive film WL as shown in FIG. 9B.

Then, the metal oxide 6 is removed by, for example, wet etching to form the gap 5 under the end of the first insulating films 42 in each stepped portion without the conductive film WL as shown in FIG. 9C. Subsequent processes are performed as in First embodiment.

An oxidation amount of the film containing metal can be easily controlled depending on an oxidation time. Therefore, the width of the metal oxide 6 formed at the end of the conductive film WL can be easily controlled. Then, by using an etching solution having a larger selectivity to the metal oxide 6 than to the first insulating film 42 and the conductive film WL to remove the metal oxide 6, the width of the gap 5 can be easily controlled.

### Third Embodiment

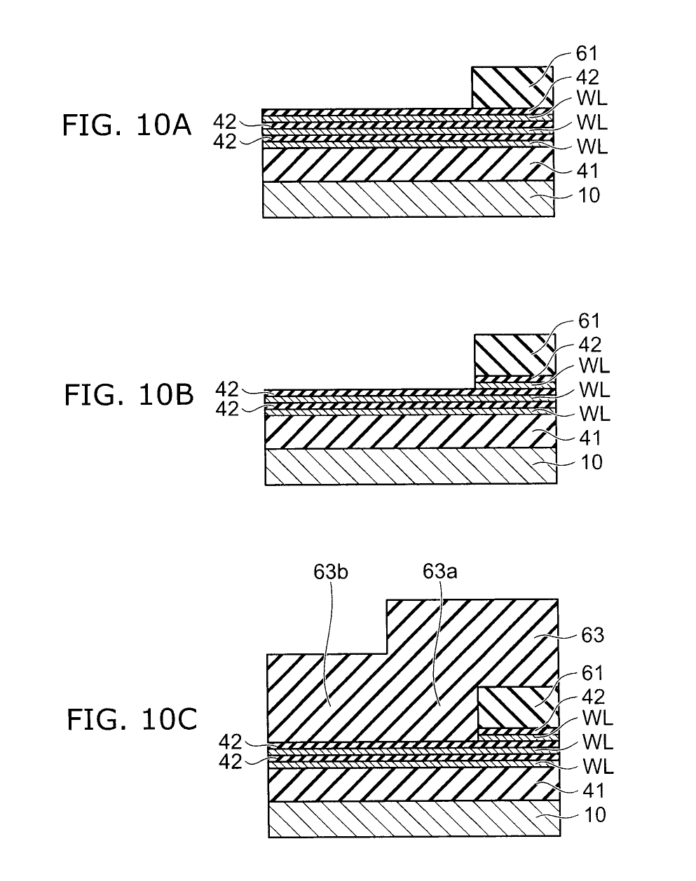

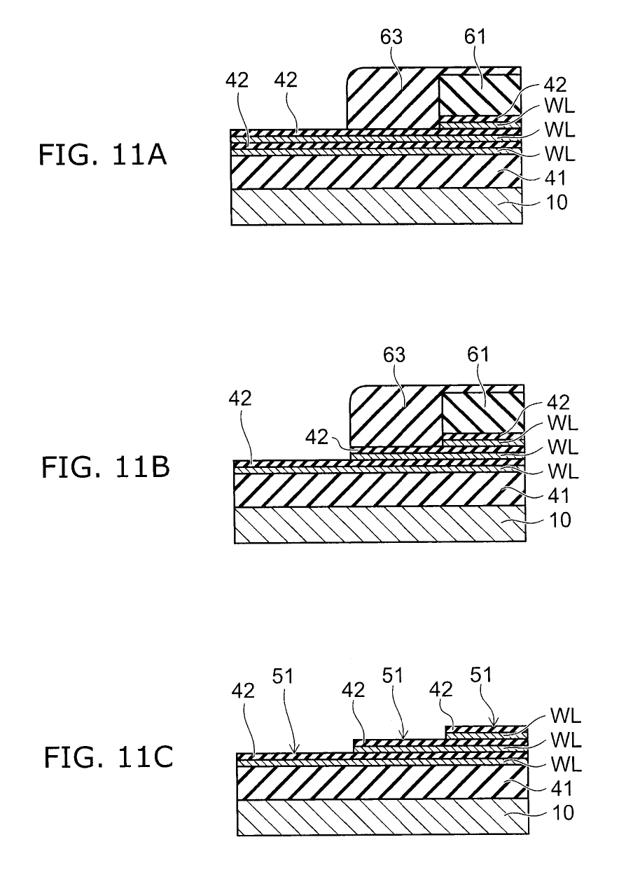

With reference to FIG. 10A to FIG. 11C, a method of forming a stepped contact portion in Third embodiment will be described.

After the stacked body is formed, the resist film 61 shown in FIG. 10A is formed on the stacked body, and the resist film 61 is exposed, developed and patterned.

Then, using the resist film 61 as a mask, the stacked body is etched according to the RIE method, for example. That is, portions of the top first insulating film 42 and the top conductive films WL, which are exposed on the resist film 61, are removed as shown in FIG. 10B.

Next, as shown in FIG. 10C, a mask layer 63 is formed on the stacked body. The mask layer 63 is, for example, a fluorocarbon film formed according to the CVD method using gas containing carbon and fluorine.

The mask layer 63 covers a portion of the top face of the stacked body, on which the resist film 61 is not formed, and a side wall and an top face of the resist film 61. An top face of the mask layer 63 has a step height that reflects a step height between the top face of the stacked body and the resist film 61.

That is, a thickness of a mask layer 63a in an area adjacent to the side wall of the resist film 61 on the stacked body is larger than a thickness of a mask layer 63b in an area away from the side wall of the resist film 61.

Then, the mask layer 63 is etched according to the RIE method, for example. Due to the difference of thickness in the mask layer 63, as shown in FIG. 11A, the mask layer 63 is left in the area lateral to the side wall of the resist film 61 on the stacked body while a part of the top face of the stacked body (top face of the first insulating films 42) is exposed.

Then, using the mask layer 63 and the resist film 61 as masks, the stacked body exposed on the mask layer 63 and the resist film 61 is etched according to the RIE method, for example. That is, the first insulating film 42 in one layer and the conductive film WL in one layer in the exposed portion from the top are removed as shown in FIG. 11B.

Then, the mask layer 63 and the resist film 61 are removed to obtain the plurality of stepped portions 51 as shown in FIG. 11C. Subsequent processes are performed as in First embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, comprising:
forming a part of a stacked body including a plurality of conductive films and a plurality of first insulating films alternately stacked into a shape of steps to form a plurality of stepped portions of different heights, each stepped portion having the first insulating film as a top face;
forming gaps under ends of the first insulating films by removing ends of the conductive films under the first insulating films in the stepped portions;
forming second insulating films having a material different from a material for the first insulating films on the respective stepped portions and in the gaps; and
forming a plurality of vias, each of the vias penetrating through the second insulating film and the first insulating film in each stepped portion and reaches the conductive film in each stepped portion.

2. The method according to claim 1, further comprising:
forming third insulating films having a material different from the material for the second insulating film on the respective second insulating film, the third insulating films being thicker than the second insulating films, wherein
each of the plurality of vias penetrates through the third insulating film, the second insulating film and the first insulating film in each stepped portion, and reaches the conductive film in each stepped portion.

3. The method according to claim 1, wherein
the forming the gap includes removing the ends of the conductive films containing silicon by isotropic etching using a gas containing fluorine.

4. The method according to claim 1, wherein
the forming the gap includes:
oxidizing the ends of the conductive films containing metal to form metal oxide at the ends, and
removing the metal oxide by wet etching.

5. The method according to claim 1, wherein
a plurality of holes, each of the holes penetrates through the second insulating film and the first insulating film in each stepped portion and reaches the conductive film in each stepped portion, are formed together at the same time and then, the vias are buried in the holes.

6. The method according to claim 1, wherein
the part of the stacked body is formed into the shape of steps by slimming a resist film formed on the stacked body and etching the first insulating film in one layer and the conductive film in one layer by use of the resist film as a mask.

7. A semiconductor device comprising:
a stacked body including a plurality of conductive films and a plurality of first insulating films alternately stacked, the stacked body having stepped portions of different heights each having the first insulating film as a top face;
second insulating films provided on the respective stepped portions, the second insulating films having a material different from a material for the first insulating films; and
a plurality of vias, each of the vias penetrates through the second insulating film and the first insulating film in each stepped portion and reaches the conductive film in each stepped portion, wherein
under an end of the first insulating film in each stepped portion, the second insulating film is provided, while the conductive film is not provided.

8. The device according to claim 7, further comprising:
third insulating films provided on the respective second insulating films, the third insulating films having a material being different from the material for the second insulating films and being thicker than the second insulating films, wherein
each of the plurality of via penetrates through the third insulating film, the second insulating film and the first insulating film in each stepped portion, and reaches the conductive film in each stepped portion.

9. The device according to claim 7, further comprising:
a channel body provided in a hole penetrating through the stacked body; and
a memory film provided between the channel body and a side wall of the hole, the memory film including a charge storage film.

10. The device according to claim 9, wherein
the stacked body includes:
a memory cell array having the channel body and the memory film; and
a stepped contact portion provided in an area on an outer side of the memory cell array, the stepped contact portion having the plurality of stepped portions and the plurality of vias.

11. The device according to claim 7, wherein
the first insulating films are silicon oxide films, and the second insulating films are silicon nitride films.

12. The device according to claim 8, wherein
the first insulating films and the third insulating films are silicon oxide films, and the second insulating films are silicon nitride films.

13. The device according to claim 7, wherein
in each stepped portion, the end of the first insulating film protrudes from an end of the conductive film immediately under the first insulating film, and the second insulating film is provided under the protruding end of the first insulating film.

14. The device according to claim 7, wherein
the first insulating film in a lower stepped portion is provided under the second insulating film provided under the end of the first insulating film.
